(19) United States
(12) Patent Application Publication
(10) Pub. No.: US 2024/0379864 A1
(43) Pub. Date: Nov. 14, 2024

(54) THIN FILM TRANSISTOR AND METHOD FOR MANUFACTURING THE SAME

(71) Applicant: ADRC. CO.KR, Seoul (KR)

(72) Inventors: Jin JANG, Seoul (KR); Jinbaek Bae, Seoul (KR)

(21) Appl. No.: 18/387,119

(22) Filed: Nov. 6, 2023

(30) Foreign Application Priority Data
May 8, 2023 (KR) 10-2023-0059363

(51) Int. Cl. H01L 29/786; H01L 21/02; H01L 21/3213; H01L 29/417

(52) U.S. Cl. CPC H01L 29/7869; H01L 21/02554; H01L 21/02595; H01L 21/02628; H01L 21/32136; H01L 29/41733

(57) ABSTRACT

A thin film transistor according to an embodiment may include a gate electrode that is positioned on a substrate; a semiconductor layer that includes a channel region overlapping the gate electrode and a gate insulating film interposed therebetween and a source region and a drain region positioned on both sides of the channel region; and a source electrode and a drain electrode that contact the source region and the drain region of the semiconductor layer, in which the semiconductor layer may include a polycrystalline oxide semiconductor, the polycrystalline oxide semiconductor includes indium, gallium, and an additional oxide in which an additional element and oxygen are bonded, and bond energy of the additional oxide may be greater than about 500 (KJ/mol).

### CROSS-REFERENCE TO RELATED APPLICATION

This application claims priority to and the benefit of Korean Patent Application No. 10-2023-0059363 filed in the Korean Intellectual Property Office on May 8, 2023, the entire contents of which are incorporated herein by reference.

### BACKGROUND

### 1. Field

The present disclosure relates to a transistor and a method for manufacturing the same.

### 2. Description of the Related Art

A thin film transistor forms a switching element with three terminals: a gate electrode to which a control signal is applied, a source electrode to which a data voltage is applied, and a drain electrode that outputs a data electrode. In addition, such a thin film transistor includes an active layer overlapping a gate electrode as a channel layer, and the active layer includes a semiconductor.

Meanwhile, as technologies such as a display including thin film transistors, develop, there is an urgent need to develop thin film transistors capable of ultra-high-speed driving. To this end, a technology using an oxide semiconductor with high electron mobility as an active layer has been developed, but a thin film transistor with improved performance is required to be used for high-speed driving.

In addition, since the manufacturing cost increases as the process of manufacturing the thin film transistor with improved performance becomes more complicated, there is a need to provide a thin film transistor capable of maintaining high performance while reducing manufacturing cost by simplifying the manufacturing process and a method for manufacturing the same.

### SUMMARY

The present disclosure attempts to provide a thin film transistor capable of lowering manufacturing costs and maintaining high performance, and a method for manufacturing the same.

However, problems to be solved by the embodiments are not limited to the above-described problems and may be variously extended in the range of technical ideas included in the embodiments.

According to an embodiment, a thin film transistor may include a gate electrode that is positioned on a substrate; a semiconductor layer that includes a channel region overlapping the gate electrode and a gate insulating film interposed therebetween and a source region and a drain region positioned on both sides of the channel region; and a source electrode and a drain electrode that contact the source region and the drain region of the semiconductor layer, in which the semiconductor layer may include a polycrystalline oxide semiconductor, the polycrystalline oxide semiconductor includes indium, gallium, and an additional oxide in which an additional element and oxygen are bonded, and bond energy of the additional oxide may be greater than about 500 (KJ/mol).

A ratio of the additional oxide in the semiconductor layer may be greater than about 0% and about 10% or less.

A band gap of the additional oxide may be about 5.0 (eV) or more.

The additional element may include at least one of aluminum (Al), lanthanum (La), yttrium (Y), hafnium (Hf), zirconium (Zr), and tantalum (Ta).

A grain size of the polycrystalline oxide semiconductor may be about 100 5 nm or less.

The source region may include a first offset region between a region overlapping the source electrode and the channel region, the drain region may include a second offset region between a region overlapping the drain electrode and the channel region, and the first offset region and the second offset region may be doped with fluorine.

The semiconductor layer may be formed by a spray coating method.

The semiconductor layer may be formed at a process temperature of about 350° C. to about 500° C.

According to an embodiment, a method for manufacturing a thin film transistor may include: forming a gate electrode on a substrate; forming a semiconductor layer that includes a channel region overlapping the gate electrode and a gate insulating film interposed therebetween and a source region and a drain region positioned on both sides of the channel region; and forming a source electrode and a drain electrode that contact the semiconductor layer, in which the forming of the semiconductor layer may include spray coating a solution including a volatile solvent, a metal precursor, and a stabilizer on the substrate, the metal precursor may include indium, gallium, and an additional element, the semiconductor layer may include an additional oxide in which the additional element and oxygen are bonded, and bond energy of the additional oxide may be greater than about 500 (KJ/mol).

The forming of the semiconductor layer may be performed at a process temperature of about 350° C. to about 500° C.

The forming of the semiconductor layer may be performed at a process temperature of about 400° C. to about 500° C.

The method may further include: plasma-processing the source region and the drain region of the semiconductor layer using a fluorine-containing gas including at least one of nitrogen trifluoride and carbon tetrafluoride.

In the plasma treatment, the semiconductor layer may be plasma-processed using the gate electrode positioned on the channel region as a mask.

The spray coating may include: preparing the solution by mixing the metal precursor and the stabilizer with the volatile solvent; spraying the solution onto the substrate together with a carrier gas; and evaporating the volatile solvent of the solution.

The spray coating may be performed at a process temperature of about 350° C. to about 500° C.

The spray coating may be performed at a process temperature of about 400° C. to about 500° C.

The forming of the semiconductor layer may repeat the spray coating several times.

According to a thin film transistor and a method for manufacturing the same according to embodiments, it is possible to lower manufacturing costs and maintain high performance.

However, it is obvious that the effects of the embodiments are not limited to the above-described effects, and may be variously extended without departing from the spirit and scope of the present disclosure.

### BRIEF DESCRIPTION OF THE DRAWINGS

FIG. 1 is a cross-sectional view of a thin film transistor according to an embodiment.

FIG. 2 is a cross-sectional view of a thin film transistor according to another embodiment.

FIGS. 3A to 3E are cross-sectional views illustrating a method for manufacturing a thin film transistor according to an embodiment.

FIGS. 4A to 4C are cross-sectional views illustrating a method for manufacturing a thin film transistor according to still another embodiment.

FIGS. 5 to 10 are graphs showing results of experimental examples.

FIGS. 11 and 12 are electron micrographs showing results of another Experimental Example.

FIG. 13 is an electron micrograph showing results of another Experimental Example.

FIG. 14 is a graph showing results of another Experimental Example.

### DETAILED DESCRIPTION

Hereinafter, embodiments of the present disclosure will be described in detail with reference to the accompanying drawings so that those skilled in the art to which the present disclosure pertains may easily practice the present disclosure. However, the present disclosure may be implemented in various different forms and is not limited to embodiments provided herein.

Portions unrelated to the description will be omitted in order to obviously describe the present disclosure, and similar components will be denoted by the same or similar reference numerals throughout the present specification.

Further, it should be understood that the accompanying drawings are provided only in order to allow embodiments of the present disclosure to be easily understood, and the spirit of the present disclosure is not limited by the accompanying drawings, but includes all the modifications, equivalents, and substitutions included in the spirit and the scope of the present disclosure.

In addition, since sizes and thicknesses of the respective components illustrated in the drawings are arbitrarily illustrated for convenience of explanation, the present disclosure is not necessarily limited to those illustrated in the drawings. In the drawings, the thickness of layers, films, panels, regions, etc., are exaggerated for clarity. In addition, in the accompanying drawings, thicknesses of some of layers and regions have been exaggerated for convenience of explanation.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, when an element is referred to as being “above” or “on” a reference element, it can be positioned on or beneath the reference element, and is not necessarily positioned “above” or “on” the reference element in an opposite direction to gravity.

In addition, unless explicitly described to the contrary, the word “comprise”, and variations such as “comprises” or “comprising”, will be understood to imply the inclusion of stated elements but not the exclusion of any other elements.

Further, throughout the specification, the word “plan view” refers to a view when a target is viewed from the top, and the word “cross-sectional view” refers to a view when a cross section of a target taken along a vertical direction is viewed from the side.

Also, throughout the specification, when it is said to be “connected”, this does not mean that two or more components are directly connected, but means that two or more components are indirectly connected through another component, that two or more components are physically connected as well as electrically connected, or that two or more components are referred to by different names depending on their location or function, but are integral.

Hereinafter, exemplary embodiments and medications in the present disclosure will be described in detail with reference to the drawings.

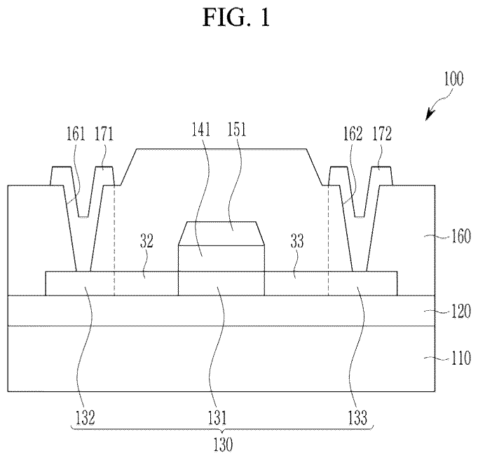

Referring to FIG. 1, a thin film transistor according to an embodiment will be described. FIG. 1 is a cross-sectional view of a thin film transistor according to an embodiment.

Referring to FIG. 1, a buffer layer 120 is positioned on the substrate 110. The buffer layer 120 may have a single-layer or multi-layer structure. In FIG. 1, the buffer layer 120 is illustrated as a single layer, but may be multi-layered according to embodiments. The buffer layer 120 may include an organic insulating material or an inorganic insulating material. For example, the buffer layer 120 may include at least one of silicon nitride (SiNx), silicon oxide (SiOx), and silicon nitric oxide (SiOxNy).

A semiconductor layer 130 including a first region 131, a second region 132, and a third region 133 is positioned on the buffer layer 120.

The semiconductor layer 130 may include a polycrystalline oxide semiconductor. A grain size of the polycrystalline oxide of the semiconductor layer 130 may be about 100 nm or less.

The oxide semiconductor may include indium (In), gallium (Ga), and an additional element having a strong bonding force with oxygen (O). The semiconductor layer 130 may include an additional oxide in which the additional element and the oxygen are bonded. For example, the additional element and the additional oxide may include at least one of aluminum (Al), lanthanum (La), yttrium (Y), hafnium (Hf), zirconium (Zr), and tantalum (Ta).

Bond energy of the additional oxide is greater than about 500 (KJ/mol). A band gap of the additional oxide may be about 5.0 (eV) or more.

A ratio of the additional oxide in the semiconductor layer 130 may be greater than about 0% and about 10% or less.

The additional oxide in the semiconductor layer 130 may be positioned on the entire surface of the semiconductor layer 130 instead of being positioned only on an upper surface of the semiconductor layer 130.

As such, the semiconductor layer 130 may further include an additional oxide in which the additional element and the oxygen are bonded to prevent unnecessary formation of carriers in the semiconductor layer 130 due to the bonding of the additional element and the oxygen, thereby suppressing leakage current and, at the same time, to prevent charge mobility from decreasing by not changing the relative ratio of indium (In) and gallium (Ga) in the oxide thin film transistor 100.

When a ratio of indium (In) and gallium (Ga) is changed to reduce the carriers in the semiconductor layer 130, the charge mobility in the semiconductor layer 130 may also decrease. However, according to an embodiment, the oxide semiconductor of the semiconductor layer 130 further includes the additional oxide, thereby preventing unnecessary formation of carriers through the additional oxide and reducing the charge mobility of the oxide semiconductor layer while maintaining a relative ratio of indium (In) and gallium (Ga).

The semiconductor layer 130 may have a thickness of about 30 nm or less, but the embodiment is not limited thereto.

The first region 131 of the semiconductor layer 130 may be a channel region, and the second region 132 and the third region 133 of the semiconductor layer 130 may be a source region and a drain region.

The semiconductor layer 130 may be formed by a spray coating method and may be crystallized without a separate annealing process. When the semiconductor layer 130 is formed by the spray coating method, the semiconductor layer 130 may be stacked at a process temperature of about 350° C. to about 500° C., and more specifically, about 400° C. to about 500° C.

By forming the semiconductor layer 130 by the spray coating method, unlike the case where the additional element is added by a doping method, a concentration of the additional element is not included to be relatively high on an upper surface of the semiconductor layer 130, but the additional element may be evenly positioned on the entire surface of the semiconductor layer 130.

In addition, by including the ratio of the additional oxide in the oxide semiconductor of the semiconductor layer 130 within about 0% to about 10%, the crystallinity of the oxide semiconductor formed by the spray coating method may be maintained to improve the performance of the transistor. The grain size of the polycrystalline oxide of the semiconductor layer 130 may be about 100 nm or less.

The second region 132 and the third region 133 of the semiconductor layer 130 may be subjected to fluorine plasma treatment. For example, the second region 132 and the third region 133 may be plasma treated with a fluorine-containing gas including at least one of nitrogen trifluoride and carbon tetrafluoride.

The second region 132 and the third region 133, which are the source region and the drain region of the semiconductor layer 130, may be doped through the plasma treatment, for example, doped to reduce a resistance and increase a carrier concentration, thereby increasing the efficiency of the channel of the thin film transistor.

A sheet resistance of the second region 132 and the third region 133 of the semiconductor layer 130 may be about 2 kohm/square (kΩ sq⁻¹) or less, and for example, a sheet resistance of the second region 132 and the third region 133 of the semiconductor layer 130 may be about 1.3 kohm/square or less, and more specifically, the sheet resistance of the second region 132 and the third region 133 of the semiconductor layer 130 may be about 1 kohm/square or less.

A gate insulating film 141 is positioned on the first region 131 of the semiconductor layer 130. The gate insulating film 141 may include an organic insulating material or an inorganic insulating material. For example, the gate insulating film 141 may include at least one of silicon nitride, silicon oxide, silicon oxynitride, and tetra ethyl ortho silicate (TEOS).

A gate electrode 151 is positioned on the gate insulating film 141. The gate electrode 151 is disposed to overlap the first region 131 of the semiconductor layer 130, and the gate insulating film 141 is positioned between the gate electrode 151 and the first region 131 of the semiconductor layer 130.

The gate electrode 151 may be a multi-film in which a metal layer including any one of copper (Cu), a copper alloy, aluminum (Al), an aluminum alloy, molybdenum (Mo), and a molybdenum alloy is stacked

A passivation layer 160 is positioned on the semiconductor layer 130, the gate insulating film 141, and the gate electrode 151. The passivation layer 160 may include at least one of silicon nitride, silicon oxide, silicon oxynitride, and tetra ethyl ortho silicate (TEOS), and may be made of an organic material such as a polyacrylates resin or a polyimides resin, a stacked film of an organic material and an inorganic material, or the like.

The passivation layer 160 includes a first contact hole 161 overlapping the second region 132 of the semiconductor layer 130 and a second contact hole 162 overlapping the third region 133 of the semiconductor layer 130.

A source electrode 171 and a drain electrode 172 are positioned on the passivation layer 160. The source electrode 171 is connected to the second region 132, which is the source region of the semiconductor layer 130, by the first contact hole 161 of the passivation layer 160, and the drain electrode 172 is connected to the third region 133 that is the drain region of the semiconductor layer 130, by the second contact hole 162 of the passivation layer 160.

The source electrode 171 and the drain electrode 172 may include aluminum-based metal, silver-based metal, or copper-based metal having low resistivity, and may have, for example, a triple film structure of a lower film including a refractory metal, such as titanium, molybdenum, chromium, and tantalum, or an alloy thereof, an intermediate film including aluminum-based metal, silver-based metal, and copper-based metal having low resistivity, and an upper film including refractory metals such as titanium, molybdenum, chromium, and tantalum.

The gate electrode 151, the source electrode 171, and the drain electrode 172 described above form a thin film transistor (TFT) together with the semiconductor layer 130, and the channel of the thin film transistor is formed in the first region 131 between the second region 132, which is the source region, and the third region 133, which is the drain region, of the semiconductors 131, 132, and 133.

A channel length of the thin film transistor may be about 6 μm or less, but the embodiment is not limited thereto.

The second region 132 of the semiconductor layer 130 may include a first offset region 32 between a region overlapping the source electrode 171 and the first region 131 that is the channel region, and the third region 133 of the semiconductor layer 130 may include a second offset region 33 between a region overlapping the drain electrode 172 and the first region 131 that is the channel region. As described above, the second region 132 and the third region 133, which are the source region and the drain region of the semiconductor layer 130 may be subjected to the fluorine plasma treatment, and for example, the second region 132 and the third region 133 may be plasma-treated with a fluorine-containing gas including at least one of nitrogen trifluoride and carbon tetrafluoride. Accordingly, the first offset region 32 and the second offset region 33 positioned on both sides of the channel region 131 may also be treated with fluorine plasma and doped with fluorine.

Therefore, the first offset region 32 and the second offset region 33 may be also plasma doped, and for example, fluorine plasma doped to prevent the increase in resistance that may occur in the first offset region 32 and second offset region 33, thereby increasing the efficiency of the channel of the thin film transistor.

According to the thin film transistor 100 according to the present embodiment, the semiconductor layer 130 may include an oxide semiconductor, the semiconductor layer 130 may be formed by the spray coating method, the semiconductor layer 130 may include an additional element whose bond energy with oxygen (O) is greater than about 500 (KJ/mol), for example, at least one of aluminum (Al), lanthanum (La), yttrium (Y), hafnium (Hf), zirconium (Zr), tantalum (Ta), and the ratio of the additional element oxide of the oxide semiconductor may be greater than about 0% and 10% or less. As such, the semiconductor layer 130 may further include an additional oxide in which the additional element and the oxygen are bonded to prevent unnecessary formation of carriers in the semiconductor layer 130 due to the bonding of the additional element and the oxygen, thereby suppressing leakage current and to prevent charge mobility from decreasing by not changing the relative ratio of indium and gallium in the oxide thin film transistor 100.

The semiconductor layer 130 of the thin film transistor 100 according to the present embodiment may be formed by the spray coating method and crystallized without a separate annealing process, so the manufacturing process may not be complicated, thereby increasing the performance of the transistor without increasing the manufacturing costs.

The second region 132 and the third region 133 of the semiconductor layer 130 of the thin film transistor 100 according to the present embodiment may be subjected to the fluorine plasma treatment, and the sheet resistance of the second region 132 and the third region 133 of the semiconductor layer 130 may be about 2 kohm/square (kΩ sq⁻¹) or less. For example, the plate resistance of the second region 132 and the third region 133 of the semiconductor layer 130 may be about 1.3 kohm/square or less, and more specifically, the sheet resistance of the second region 132 and the third region 133 of the semiconductor layer 130 may be about 1 kohm/square or less to decrease the resistance of the source region and the drain region and increase the carrier concentration, thereby increasing the efficiency of the channel of the thin film transistor.

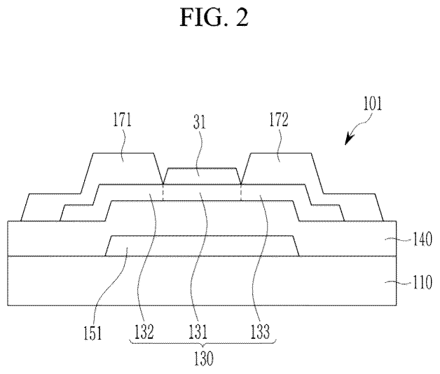

Referring to FIG. 2, the thin film transistor 101 according to the embodiment will be described. FIG. 2 is a cross-sectional view of a thin film transistor according to another embodiment.

Referring to FIG. 2, the gate electrode 151 may be positioned on the substrate 110, and the gate insulating film 141 may be positioned on the gate electrode 151.

The gate electrode 151 may be a multi-film in which a metal layer including any one of copper (Cu), a copper alloy, aluminum (Al), an aluminum alloy, molybdenum (Mo), and a molybdenum alloy is stacked.

The gate insulating film 141 may include an organic insulating material or an inorganic insulating material. For example, the gate insulating film 141 may include at least one of silicon nitride, silicon oxide, silicon oxynitride, and tetra ethyl ortho silicate (TEOS).

A semiconductor layer 130 including a first region 131, a second region 132, and a third region 133 is positioned on the gate insulating film 141.

The semiconductor layer 130 may include a polycrystalline oxide semiconductor. The grain size of the polycrystalline oxide of the semiconductor layer 130 may be about 100 nm or less.

The oxide semiconductor may include indium (In), gallium (Ga), and an additional element having a strong bonding force with oxygen (O). The semiconductor layer 130 may include an additional oxide in which the additional element and the oxygen are bonded. For example, the additional element and the additional oxide may include at least one of aluminum (Al), lanthanum (La), yttrium (Y), hafnium (Hf), zirconium (Zr), and tantalum (Ta).

Bond energy of the additional oxide is greater than about 500 (KJ/mol). A band gap of the additional oxide may be about 5.0 (eV) or more.

A ratio of the additional oxide in the semiconductor layer 130 may be greater than about 0% and about 10% or less.

As such, the semiconductor layer 130 may further include an additional oxide in which additional element and oxygen are bonded to prevent unnecessary formation of carriers in the semiconductor layer 130 due to the bonding of the additional element and the oxygen, thereby suppressing leakage current and, at the same time, to prevent charge mobility from decreasing by not changing the relative ratio of indium (In) and gallium (Ga) in the oxide semiconductor layer 130, thereby preventing the performance degradation of the thin film transistor 100.

The semiconductor layer 130 may be formed by a spray coating method and may be crystallized without a separate annealing process. When the semiconductor layer 130 is formed by the spray coating method, a deposition temperature may be about 350° C. to about 500° C., and more specifically, about 400° C. to about 500° C.

The second region 132 and the third region 133 of the semiconductor layer 130 may be subjected to fluorine plasma treatment. For example, the second region 132 and the third region 133 may be plasma treated with a fluorine-containing gas including at least one of nitrogen trifluoride and carbon tetrafluoride.

The second region 132 and the third region 133, which are the source region and the drain region of the semiconductor layer 130, may be doped through the plasma treatment to reduce a resistance and increase a carrier concentration, thereby increasing the efficiency of the channel of the thin film transistor.

A sheet resistance of the second region 132 and the third region 133 of the semiconductor layer 130 may be about 2 kohm/square (kΩ sq⁻¹) or less, and for example, a sheet resistance of the second region 132 and the third region 133 of the semiconductor layer 130 may be about 1.3 kohm/square or less, and more specifically, the sheet resistance of the second region 132 and the third region 133 of the semiconductor layer 130 may be about 1 kohm/square or less.

A blocking layer 31 may be positioned on the first region 131 that is the channel region of the semiconductor layer 130. The blocking layer 31 may include an inorganic insulating film.

The source electrode 171 is positioned on the second region 132, which is the source region of the semiconductor layer 130, and the drain electrode 172 is positioned on the third region 133 which is the drain region of the semiconductor layer 130.

The source electrode 171 and the drain electrode 172 may include aluminum-based metal, silver-based metal, or copper-based metal having low resistivity, and may have, for example, a triple film structure of a lower film including a refractory metal, such as titanium, molybdenum, chromium, and tantalum, or an alloy thereof, an intermediate film containing aluminum-based metal, silver-based metal, and copper-based metal having low resistivity, and an upper film including refractory metals such as titanium, molybdenum, chromium, and tantalum.

The gate electrode 151, the source electrode 171, and the drain electrode 172 described above form a thin film transistor together with the semiconductor layer 130, and the channel of the thin film transistor is formed in the first region 131 between the second region 132, which is the source region, and the third region 133, which is the drain region, of the semiconductors 131, 132, and 133.

According to the thin film transistor 100 according to the present embodiment, the semiconductor layer 130 may include an oxide semiconductor, the semiconductor layer 130 may be formed by the spray coating method, the semiconductor layer 130 may further include an additional oxide in which the additional element and the oxygen are bonded, the additional element may include at least one of aluminum (Al), lanthanum (La), yttrium (Y), hafnium (Hf), zirconium (Zr), and tantalum (Ta), and a ratio of the additional oxide in the semiconductor layer 130 may be greater than about 0% and about 10% or less. As such, the semiconductor layer 130 may further include an additional oxide in which the additional element and the oxygen are bonded to prevent unnecessary formation of carriers in the semiconductor layer 130 due to the bonding of the additional element and the oxygen, thereby suppressing leakage current and to prevent charge mobility from decreasing by not changing the relative ratio of indium and gallium in the oxide semiconductor layer 130, thereby preventing the performance degradation of the thin film transistor 100.

The semiconductor layer 130 of the thin film transistor 100 according to the present embodiment may be formed by the spray coating method and crystallized without a separate annealing process, so the manufacturing process may not be complicated, thereby increasing the performance of the transistor without increasing the manufacturing costs.

The second region 132 and the third region 133 of the semiconductor layer 130 of the thin film transistor 100 according to the present embodiment may be subjected to the fluorine plasma treatment, and the sheet resistance of the second region 132 and the third region 133 of the semiconductor layer 130 may be about 2 kohm/square (kΩ sq⁻¹) or less. For example, the plate resistance of the second region 132 and the third region 133 of the semiconductor layer 130 may be about 1.3 kohm/square or less, and more specifically, the sheet resistance of the second region 132 and the third region 133 of the semiconductor layer 130 may be about 1 kohm/square or less to decrease the resistance of the source region and the drain region and increase the carrier concentration, thereby increasing the efficiency of the channel of the thin film transistor.

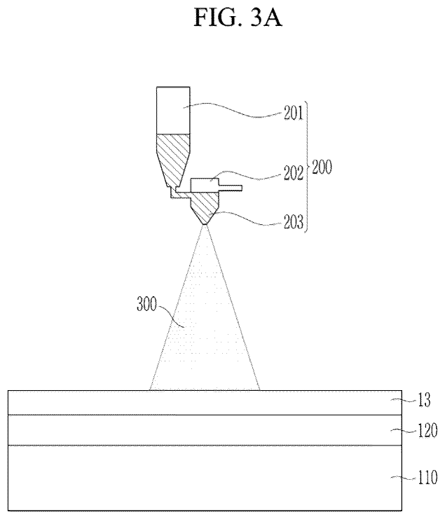

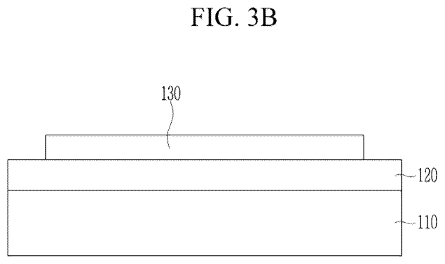

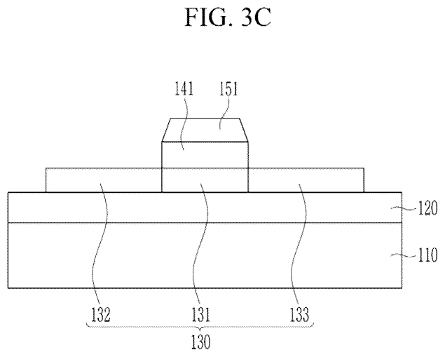

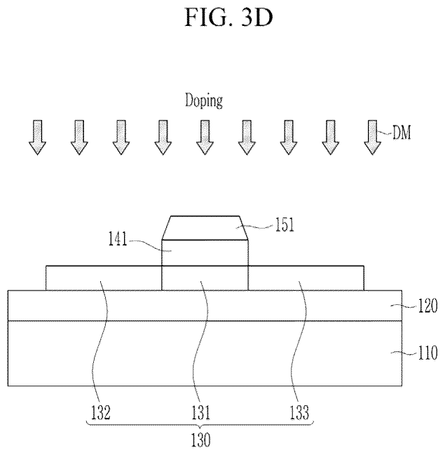

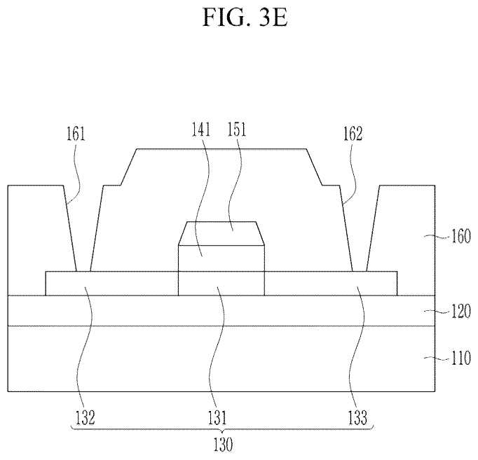

A method of manufacturing a thin film transistor 100 according to an embodiment will be described with reference to FIGS. 3A to 3E together with FIG. 1. FIGS. 3A to 3E are cross-sectional views illustrating a method for manufacturing a thin film transistor according to an embodiment.

As illustrated in FIG. 3A, the buffer layer 120 is stacked on the substrate 110, and the semiconductor thin film 13 constituting the semiconductor layer 130 is stacked on the buffer layer 120.

The semiconductor thin film 13 may be formed by the spray coating method using a spray coating device 200.

The spray coating device 200 may include a solution supply unit 201 for receiving a spray solution, a gas supply unit 202, and a nozzle 203.

The step of stacking the semiconductor thin film 13 is a step of preparing a process solution in which a precursor and a stabilizer of metal included in the oxide semiconductor of the semiconductor layer 130 are mixed with a volatile solvent, spraying the process solution through the nozzle 203 together with the carrier gas supplied through the gas supply unit 202, and evaporating the volatile solvent included in the second process solution. The semiconductor thin film 13 may be stacked by repeating the process of spraying and evaporating the process solution to form a thin semiconductor thin film several times.

For example, the indium (In) precursor may include indium (III) chloride (InCl₃), the gallium (Ga) precursor may include gallium(III) nitrate hydrate (Ga (NO₃)₃·xH₂O), the stabilizer may include ammonium acetate (CH₃CO₂NH₄) (AA), and the solvent may include 2-methoxyethanol (CH₃OCH₂CH₂OH).

The process solution may further include an additional element whose bond energy with oxygen (O) is greater than about 500 (KJ/mol). For example, the additional element may include at least one of indium (In), gallium (Ga), aluminum (Al), lanthanum (La), yttrium (Y), hafnium (Hf), zirconium (Zr), and tantalum (Ta).

A band gap of the additional oxide in which the additional element and the oxygen are combined may be about 5.0 (eV) or more.

The stacking of the semiconductor thin film 13 may be performed at a process temperature of about 350° C. to about 500° C., and more specifically, about 400° C. to about 500° C.

As the spray coating process is repeated, the thickness of the semiconductor thin film 13 may increase, and the crystal size of the semiconductor thin film 13 may increase.

In order to stack the semiconductor layer 130, when the spray coating process is repeated, the crystals may be aligned in a line from the lower surface to the upper surface along the thickness direction of the semiconductor layer 130 while the thin semiconductor layer is stacked several times.

When the spray coating process is performed, a crystal nucleus is formed in the semiconductor layer at the beginning of the process, and as an additional semiconductor layer is stacked on the crystal nucleus by the spray coating process, crystals grow around the crystal nucleus, resulting in crystallization.

The semiconductor thin film 13 is stacked by the spray coating method to form the crystallized oxide semiconductor layer, and then patterned to form the semiconductor layer 130 as illustrated in FIG. 3B.

A ratio of the additional oxide in the semiconductor layer 130 may be greater than about 0% and about 10% or less.

The additional oxide in the semiconductor layer 130 may be positioned on the entire surface of the semiconductor layer 130 instead of being positioned only on an upper surface of the semiconductor layer 130.

As illustrated in FIG. 3C, the gate insulating film 141 and the gate electrode 151 may be formed to overlap the first region of the semiconductor layer 130.

The gate insulating film 141 and the gate electrode 151 may be formed by sequentially stacking the gate insulating film layer and the gate electrode layer on the semiconductor layer 130 and then patterning them.

As illustrated in FIG. 3D, the semiconductor layer 130 may be plasma-treated using a process gas DM using the gate insulating film 141 and the gate electrode 151 as a mask, and the second region 132 and the third region 133 of the semiconductor layer 130 may be doped with impurities through the plasma treatment.

For example, the process gas DM may include fluorine, and more specifically, include at least one of nitrogen trifluoride and carbon tetrafluoride. Through this, the second region 132 and the third region 133 of the semiconductor layer 130 may be doped with fluorine.

After performing the plasma processing on the second region 132 and the third region 133, as illustrated in FIG. 3E, a passivation layer 160 is stacked, a first contact hole 161, a second contact hole 162 are formed in the passivation layer 160, and then, the source electrode 171 connected to the second region 132 of the semiconductor layer 130 through the first contact hole 161 and the drain electrode 172 connected to the third region 133 of the semiconductor layer 130 through the second contact hole 162 are formed, so as illustrated in FIG. 1, the thin film transistor may be formed.

According to the method for manufacturing a thin film transistor according to the present embodiment, the semiconductor layer 130 may be formed to include an additional element having a high bonding strength with oxygen, in addition to indium (In) and gallium (Ga) constituting the semiconductor layer 130, for example, at least one additional element of aluminum (Al), lanthanum (La), yttrium (Y), hafnium (Hf), zirconium (Zr), and tantalum (Ta). The semiconductor layer 130 may include an additional element whose bond energy with oxygen (O) is greater than about 500 (KJ/mol), for example, at least one of aluminum (Al), lanthanum (La), yttrium (Y), and hafnium (Hf), zirconium (Zr), and tantalum (Ta), and a ratio of the oxide of the additional element in the oxide semiconductor may be greater than about 0% to about 10% or less. The semiconductor layer 130 may further include an additional oxide in which the additional element and the oxygen are bonded to prevent unnecessary formation of carriers in the semiconductor layer 130 due to the bonding of the additional element and the oxygen, thereby suppressing leakage current and to prevent charge mobility from decreasing by not changing the relative ratio of indium and gallium in the oxide thin film transistor 100.

The semiconductor layer 130 may be formed by the spray coating method. For example, a process of forming a thin semiconductor thin film by evaporating a volatile solvent after spraying a solution, in which the precursor and stabilizer of the material included in the oxide semiconductor are mixed with the volatile solvent, together with a carrier gas such as nitrogen at a temperature of about 350° to about 500° is repeated several times, thereby forming the crystallized oxide semiconductor layer 130 without an additional crystallization process.

The plasma treatment is performed using the gate insulating film 141 and the gate electrode 151 as the mask, and the second region 132 and the third region 133 of the semiconductor layer 130 are doped with impurities, for example, fluorine, so it is possible to increase the efficiency of the channel of the thin film transistor by reducing the resistance and increasing the carrier concentration.

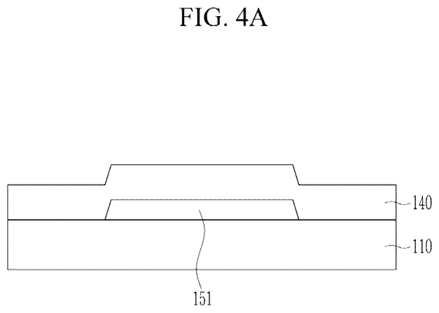

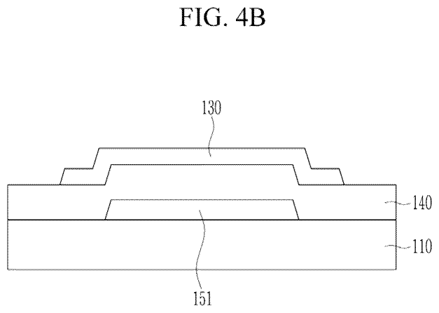

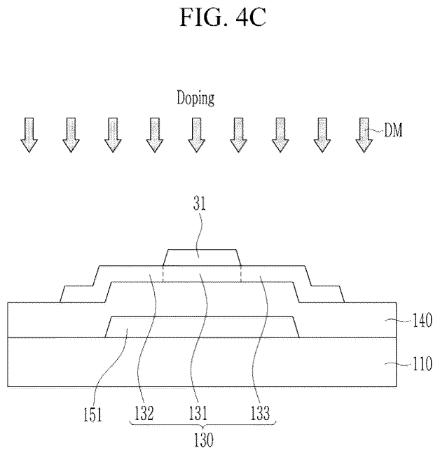

A method of manufacturing a thin film transistor 101 according to another embodiment will be described with reference to FIGS. 4A to 4C together with FIG. 2. FIGS. 4A to 4C are cross-sectional views illustrating a method for manufacturing a thin film transistor according to still another embodiment.

As illustrated in FIG. 4A, the gate electrode 151 is formed on the substrate 110 and the gate insulating film 140 is formed on the gate electrode 151.

As illustrated in FIG. 4B, the semiconductor layer 130 is formed on the gate insulating film 140 by the spray coating method at a process temperature of about 400° C. to about 500° C., and more specifically, about 440° C. to about 500° C. A process of forming the semiconductor layer 130 by the spray coating method is similar to the process illustrated in FIGS. 3A and 3B, and thus, a detailed description thereof will be omitted.

The semiconductor layer 130 may be formed by the spray coating method. For example, a process of forming a thin semiconductor thin film by evaporating a volatile solvent after spraying a solution, in which the precursor and stabilizer of the material included in the oxide semiconductor are mixed with the volatile solvent, together with a carrier gas such as nitrogen at a temperature of about 350° C. to about 500° C. is repeated several times, thereby forming the crystallized oxide semiconductor layer 130 without an additional crystallization process.

The semiconductor layer 130 may include indium (In) and gallium (Ga), and may be formed to include an additional element whose bond energy with oxygen (O) is greater than about 500 (KJ/mol), for example, at least one of aluminum (Al), lanthanum (La), yttrium (Y), and hafnium (Hf), zirconium (Zr), and tantalum (Ta).

A ratio of the additional oxide in the semiconductor layer 130 may be greater than about 0% and about 10% or less.

The additional oxide in the semiconductor layer 130 may be positioned on the entire surface of the semiconductor layer 130 instead of being positioned only on an upper surface of the semiconductor layer 130.

The semiconductor layer 130 may be formed to further include an additional oxide in which the additional element and the oxygen are bonded to prevent unnecessary formation of carriers in the semiconductor layer 130 due to the bonding of the additional element and the oxygen, thereby suppressing leakage current and to prevent charge mobility from decreasing by not changing the relative ratio of indium and gallium in the oxide semiconductor layer 130, thereby preventing the performance degradation of the thin film transistor 100.

As illustrated in FIG. 4C, a blocking layer 31 is formed on the semiconductor layer 130, and the semiconductor layer 130 may be plasma-treated using the process gas (DM) using the blocking layer 31 as the mask, and the second region 132 and the third region 133 of the semiconductor layer 130 may be doped with impurities through the plasma treatment.

For example, the process gas DM may contain fluorine, and more specifically, contain at least one of nitrogen trifluoride and carbon tetrafluoride. Through this, the second region 132 and the third region 133 of the semiconductor layer 130 may be doped with fluorine.

After performing the plasma treatment on the second region 132 and the third region 133, the source electrode 171 and the drain electrode 172 are formed on the second region 132 and the third region 133 of the semiconductor layer 130, thereby forming the thin film transistor 101 as illustrated in FIG. 2.

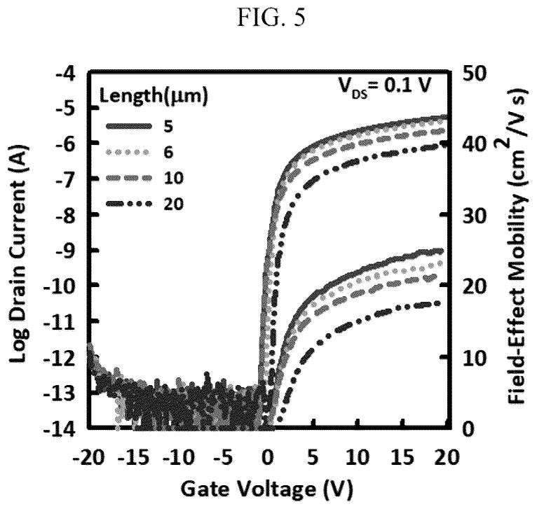

Then, experimental examples will be described with reference to FIGS. 5 to 10. FIGS. 5 to 10 are graphs showing results of experimental examples.

Then, experimental examples will be described with reference to FIGS. 5 to 10. FIGS. 5 to 10 are graphs showing results of experimental examples.

In this experimental example, in a first case in which the oxide semiconductor is formed by the spray method so that indium and gallium are included in a ratio of about 70: about 30, a second case in which the oxide semiconductor is formed by the spray method so that indium, gallium, and aluminum are included in a ratio of about 69.3: about 29.7: about 1, a third case in which the oxide semiconductor is formed by the spray method so that indium, gallium, and aluminum are included in a ratio of about 68: about 29: about 3, and a fourth case in which the oxide semiconductor is formed by the spray method so that indium, gallium, and aluminum are included in a ratio of about 66.5: about 28.5: about 5, the transistor characteristics were measured while changing the channel length of the transistor.

The results of the first case were shown in Table 1.

Table 1 showed the results of field-effect Mobility (μ_{FE}), threshold voltage (Vth), sub-threshold voltage swing (SS), and saturated mobility (μ_{SAT}) according to the change in the channel length L.

TABLE 1

| L | μ_{FE} | Vth | SS | μ_{SAT} |
|---|---|---|---|---|
| (μm) | (cm²/Vs) | (V) | (V/dec.) | (cm²/Vs) |
| 4 | 23.82 | −2.0 | 0.140 | 36.70 |
| 5 | 23.39 | −2.2 | 0.163 | 31.61 |
| 6 | 35.14 | −1.4 | 0.123 | 51.69 |
| 10 | 32.16 | −0.2 | 0.122 | 40.30 |
| 20 | 26.33 | 0.6 | 0.170 | 30.16 |

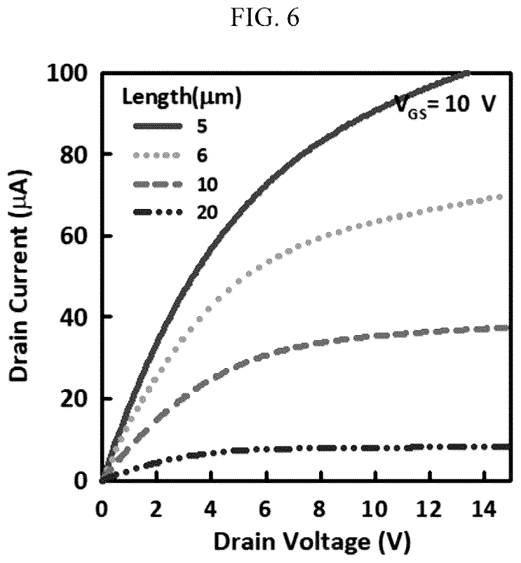

The results of the second case are shown in Table 2 and FIGS. 5 and 6. Compared to the first case, according to the second case, it could be seen that the threshold voltage (Vth) of the transistor including the oxide semiconductor is shifted to a positive (+) side and the stability is improved.

TABLE 2

| L | μ_{FE} | Vth | SS | μ_{SAT} |
|---|---|---|---|---|
| (μm) | (cm²/Vs) | (V) | (V/dec.) | (cm²/Vs) |
| 5 | 24.93 | −0.4 | 0.209 | 48.09 |
| 6 | 23.28 | 0.1 | 0.189 | 37.48 |
| 10 | 21.57 | −0.5 | 0.243 | 28.23 |
| 20 | 18.04 | 0.6 | 0.225 | 17.63 |

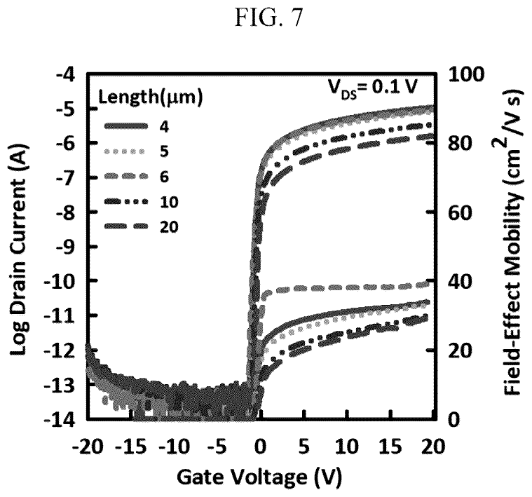

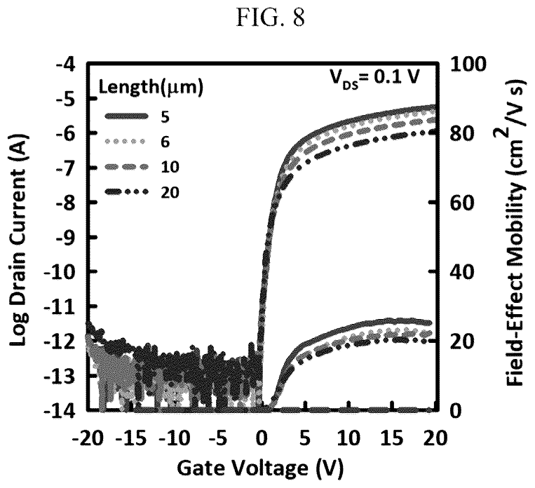

The results of the third case are shown in Table 3 and FIGS. 7 and 8. Compared to the first case, according to the third case, it could be seen that the threshold voltage (Vth) of the transistor including the oxide semiconductor is shifted to a positive (+) side and the stability is improved.

TABLE 3

| L | μ_{FE} | Vth | SS | μ_{SAT} |
|---|---|---|---|---|
| (μm) | (cm²/Vs) | (V) | (V/dec.) | (cm²/Vs) |
| 5 | 25.85 | 0.3 | 0.346 | 42.36 |
| 6 | 23.20 | 0.4 | 0.237 | 46.11 |
| 10 | 22.31 | 0.3 | 0.361 | 31.86 |
| 20 | 20.30 | 0.1 | 0.250 | 24.59 |

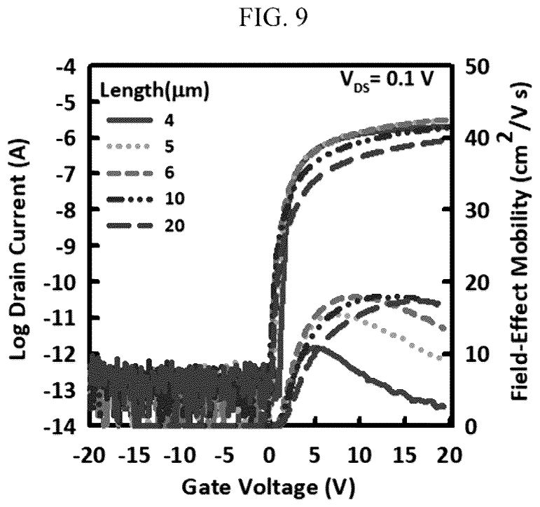

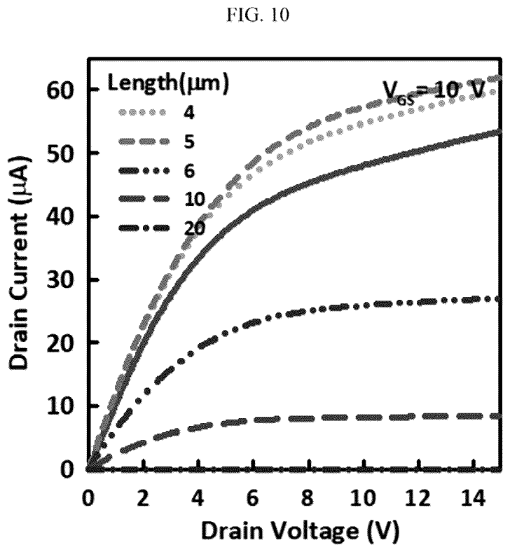

The results of the fourth case are shown in Table 4 and FIGS. 9 and 10. Compared to the first case, according to the fourth case, it could be seen that the threshold voltage (Vth) of the transistor including the oxide semiconductor is shifted to a positive (+) side and the stability is improved.

TABLE 4

| L | μ_{FE} | Vth | SS | μ_{SAT} |
|---|---|---|---|---|
| (μm) | (cm²/Vs) | (V) | (V/dec.) | (cm²/Vs) |
| 4 | 10.84 | 1.4 | 0.149 | 35.50 |
| 5 | 15.52 | 0.9 | 0.253 | 35.38 |
| 6 | 17.91 | 0.4 | 0.256 | 36.03 |
| 10 | 18.03 | 0.3 | 0.222 | 31.11 |
| 20 | 17.31 | 0.6 | 0.255 | 21.55 |

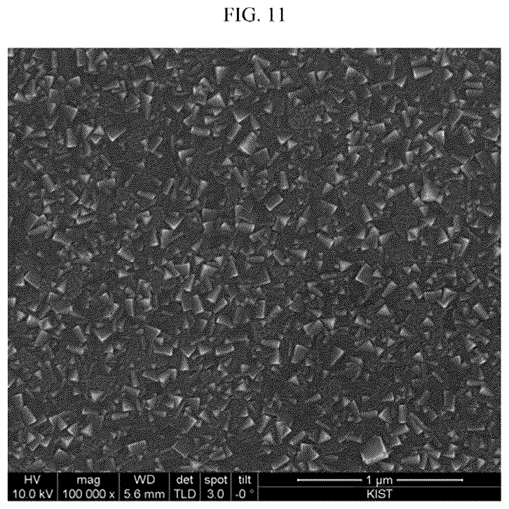

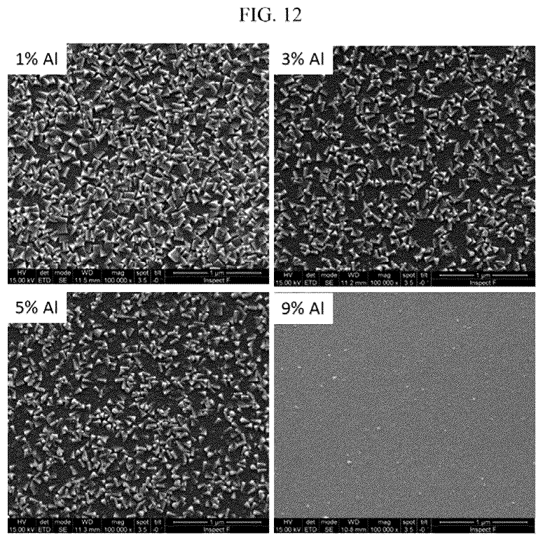

Then, another experimental example will be described with reference to FIGS. 11 and 12. In this experimental example, when the oxide semiconductor is formed by the spray deposition method, the first case that does not include an additional element and the second case that is formed to include aluminum (Al) as an additional element are formed. In the second case, the ratio of aluminum was formed to include about 1%, about 3%, about 5%, and about 9%

An electron micrograph of oxide semiconductors formed for the first case was illustrated in FIG. 11, and an electron micrograph of the oxide semiconductors formed for the second case was shown in FIG. 12 Referring to FIG. 12 together with FIG. 11, similar to the first case which does not include any additional elements, in the case where it is formed to include aluminum (Al) of about 1%, about 3%, about 5%, and about 9% as an additional element, it could be seen that the oxide semiconductor layer is formed to have a polycrystalline structure.

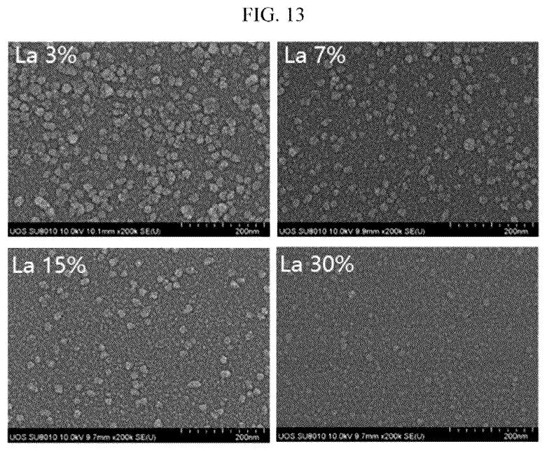

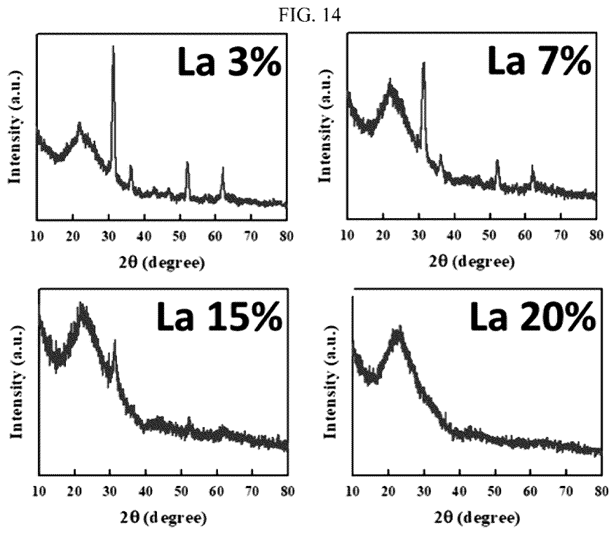

Referring to FIG. 14 together with FIG. 13, another experimental example will be described.

In this experimental example, when the oxide semiconductor is formed by the spray deposition method, it was formed to include lanthanum (La) as an additional element, and it was formed to include lanthanum (La) of a ratio of about 3%, about 7%, about 15%, and about 30%. The electron micrograph of the oxide semiconductor layer formed for each case was shown in FIG. 13, and an XRD analysis result was shown in FIG. 14.

Referring to FIGS. 13 and 14, when the oxide semiconductor is formed by the spray deposition method, in the two cases in which lanthanum (La) greater than about 0% to about 10% or less is included as an additional element, as a result of the X-ray diffraction (XRD), it could be seen that the polycrystallinity of the oxide semiconductor is maintained well so that the crystal of the oxide semiconductor has a main peak value at a 2θ value of about 31°. On the other hand, in the case where it is formed to include lanthanum (La) of about 15% to about 30% as an additional element, as a result of XRD (X-ray diffraction), it could be seen that the crystallinity of the oxide semiconductor was not shown, and the crystallinity was also lowered as the result of the electron micrograph.

As such, as in the thin film transistor and the method of manufacturing a thin film transistor according to the above-described embodiments, the oxide semiconductor layer is formed by the spray coating process, and the oxide semiconductor layer is formed to further include an additional oxide in which an additional element having high bonding energy with oxygen is bonded with oxygen, but in the case where the ratio of the additional oxide is formed within about 0% to about 10%, it could be seen that the performance of the transistor including the oxide semiconductor may be improved, the stability may increase, and the polycrystallinity of the oxide semiconductor may be maintained well.

Although preferred embodiments of the present disclosure have been described above, the present disclosure is not limited thereto, and the present disclosure can be variously modified within the scope of the claims, the detailed description of this disclosure, and the appended drawings, and it is natural that various modifications also fall within the scope of the present disclosure.

### DESCRIPTION OF SYMBOLS

110: Substrate
120: Buffer layer
130: Semiconductor layer
141: Gate insulating film
151: Gate electrode
160: Passivation layer
161, 162: Contact hole
171: Source electrode
172: Drain electrode

What is claimed is:

1. A thin film transistor, comprising:
a gate electrode that is positioned on a substrate;
a semiconductor layer that includes a channel region overlapping the gate electrode and a gate insulating film interposed therebetween and a source region and a drain region positioned on both sides of the channel region; and
a source electrode and a drain electrode that contact the source region and the drain region of the semiconductor layer,
wherein the semiconductor layer includes a polycrystalline oxide semiconductor,
the polycrystalline oxide semiconductor includes indium, gallium, and an additional oxide in which an additional element and oxygen are bonded, and
bond energy of the additional oxide is greater than about 500 (KJ/mol).

2. The thin film transistor of claim 1, wherein:
a ratio of the additional oxide in the semiconductor layer is greater than about 0% and about 10% or less.

3. The thin film transistor of claim 2, wherein:
a band gap of the additional oxide is about 5.0 (eV) or more.

4. The thin film transistor of claim 2, wherein:
the additional element includes at least one of aluminum (Al), lanthanum (La), yttrium (Y), hafnium (Hf), zirconium (Zr), and tantalum (Ta).

5. The thin film transistor of claim 4, wherein:
a grain size of the polycrystalline oxide semiconductor is about 100 nm or less.

6. The thin film transistor of claim 1, wherein:
the source region includes a first offset region between a region overlapping the source electrode and the channel region,
the drain region includes a second offset region between a region overlapping the drain electrode and the channel region, and
the first offset region and the second offset region are doped with fluorine.

7. The thin film transistor of claim 1, wherein:
the semiconductor layer is formed by a spray coating method.

8. The thin film transistor of claim 7, wherein:
the semiconductor layer is formed at a process temperature of about 350° C. to about 500° C.

9. A method for manufacturing a thin film transistor, comprising:
forming a gate electrode on a substrate;
forming a semiconductor layer that includes a channel region overlapping the gate electrode and a gate insulating film interposed therebetween and a source region and a drain region positioned on both sides of the channel region; and
forming a source electrode and a drain electrode that contact the semiconductor layer,
wherein the forming of the semiconductor layer includes spray coating a solution including a volatile solvent, a metal precursor, and a stabilizer on the substrate,
the metal precursor includes indium, gallium, and an additional element,
the semiconductor layer includes an additional oxide in which the additional element and oxygen are bonded, and
bond energy of the additional oxide is greater than about 500 (KJ/mol).

10. The method of claim 9, wherein:
the forming of the semiconductor layer is performed at a process temperature of about 350° C. to about 500° C.

11. The method of claim 10, wherein:
the forming of the semiconductor layer is performed at a process temperature of about 400° C. to about 500° C.

12. The method of claim 9, wherein:
a band gap of the additional oxide is about 5.0 (eV) or more.

13. The method of claim 9, wherein:
the additional element includes at least one of aluminum (Al), lanthanum (La), yttrium (Y), hafnium (Hf), zirconium (Zr), and tantalum (Ta).

14. The method of claim 9, wherein:
a ratio of the additional oxide in the semiconductor layer is greater than about 0% and about 10% or less.

15. The method of claim 9, further comprising:
plasma-processing the source region and the drain region of the semiconductor layer using a fluorine-containing gas including at least one of nitrogen trifluoride and carbon tetrafluoride.

16. The method of claim 15, wherein:
in the plasma treatment, the semiconductor layer is plasma-processed using the gate electrode positioned on the channel region as a mask.

17. The method of claim 9, wherein:
the spray coating includes:
preparing the solution by mixing the metal precursor and the stabilizer with the volatile solvent;
spraying the solution onto the substrate together with a carrier gas; and
evaporating the volatile solvent of the solution.

18. The method of claim 17, wherein:
the spray coating is performed at a process temperature of about 350° C. to about 500° C.

19. The method of claim 18, wherein:
the spray coating is performed at a process temperature of about 400° C. to about 500° C.

20. The method of claim 18, wherein:
the forming of the semiconductor layer repeats the spray coating several times.
